(19) United States
(12) Patent Application Publication
(10) Pub. No.: US 2025/0255104 A1
(43) Pub. Date: Aug. 7, 2025

(54) DISPLAY DEVICE

(71) Applicant: Samsung Display Co., LTD., Yongin-si (KR)

(72) Inventors: Hyun Eok SHIN, Yongin-si (KR); Joon Yong PARK, Yongin-si (KR); Su Kyoung YANG, Yongin-si (KR); Dong Min LEE, Yongin-si (KR)

(21) Appl. No.: 18/794,491

(22) Filed: Aug. 5, 2024

(30) Foreign Application Priority Data
Feb. 5, 2024 (KR) 10-2024-0017562

(51) Int. Cl. H10K 59/122; H10K 59/80

(52) U.S. Cl. CPC H10K 59/122; H10K 59/80522; H10K 59/873

(57) ABSTRACT

A display device is provided. A display device includes a pixel electrode above a substrate, a pixel-defining layer above the substrate, and having a portion above the pixel electrode, an emissive layer above the pixel electrode, a common electrode above the emissive layer, a first bank above the pixel-defining layer, a second bank above the first bank, and protruding beyond a side surface of the first bank, and an auxiliary electrode above the pixel-defining layer.

### CROSS-REFERENCE TO RELATED APPLICATION

The present application claims priority to, and the benefit of, Korean Patent Application No. 10-2024-0017562, filed on Feb. 5, 2024, in the Korean Intellectual Property Office, the entire disclosure of which is incorporated herein by reference.

### BACKGROUND

### 1. Field

The present disclosure relates to a display device.

### 2. Description of the Related Art

As the information-oriented society evolves, various demands for display devices are ever increasing. Recently, display devices are employed by devices in the form of glasses for providing virtual reality and augmented reality. To apply a display device to devices in the form of glasses, it is suitable to implement a display device in a relatively very small size of about 2 inches or less with a high pixel integration to achieve high resolution. For example, a display device may have a high pixel integration of about 400 PPI (pixels per inch) or higher.

A display device may include a variety of optical devices, such as an image sensor for capturing an image on the front side, a proximity sensor for detecting whether a user is located close to the front side of the display device, an illuminance sensor for detecting the illuminance of the front side of the display device, and an iris sensor for recognizing a user's iris. Optical devices may be located to overlap with a display panel. The optical devices may be located in a hole formed in the front surface of a display device.

### SUMMARY

Aspects of the present disclosure provide a display device in which separated emissive layers or common electrodes can be formed in each emission area without a mask process.

Aspects of the present disclosure also provide a display device that can decrease or prevent reduction of light incident on an optical device even though the optical device overlaps with the display panel.

It should be noted that aspects of the present disclosure are not limited to the above-mentioned aspect, and that other aspects of the present disclosure will be apparent to those skilled in the art from the following descriptions.

According to one or more embodiments of the present disclosure, a display device includes a pixel electrode above a substrate, a pixel-defining layer above the substrate, and having a portion above the pixel electrode, an emissive layer above the pixel electrode, a common electrode above the emissive layer, a first bank above the pixel-defining layer, a second bank above the first bank, and protruding beyond a side surface of the first bank, and an auxiliary electrode above the pixel-defining layer.

The second bank may overlap with the common electrode and the auxiliary electrode in a thickness direction of the substrate.

The first bank may be between the auxiliary electrode and the common electrode.

The auxiliary electrode and the common electrode may contact the side surface of the first bank.

The common electrode and the auxiliary electrode may be electrically connected with each other.

The display device may further include a sub-auxiliary electrode above the second bank, and including a same material as the auxiliary electrode.

The auxiliary electrode may include transparent conductive oxide (TCO).

The first bank and the second bank may include different respective metal materials.

A first distance, in plan view, between a first portion of a side surface of the second bank and a first portion of the side surface of the first bank adjacent to the common electrode may be substantially equal to a second distance, in plan view, between a second portion of the side surface of the second bank and a second portion of the side surface of the first bank adjacent to the auxiliary electrode.

The display device may further include a thin-film encapsulation layer above the common electrode and the auxiliary electrode.

The thin-film encapsulation layer may include a lower inorganic encapsulation layer above the common electrode and the second bank, an organic encapsulation layer above the lower inorganic encapsulation layer, and an upper inorganic encapsulation layer above the organic encapsulation layer.

The lower inorganic encapsulation layer may include a first inorganic layer above the common electrode, and a second inorganic layer above the auxiliary electrode, the first inorganic layer and the second inorganic layer being spaced apart from each other.

The display device may further include a sub-auxiliary electrode above the second bank and the lower inorganic encapsulation layer, and including a same material as the auxiliary electrode.

According to one or more embodiments of the present disclosure, a display device includes a substrate including an emission area, a light-transmitting area, and a light-blocking area between the emission area and the light-transmitting area, a light-emitting element above the substrate in the emission area, an auxiliary electrode above the substrate in the light-transmitting area, a first bank above the substrate in the light-blocking area, and a second bank above the substrate in the light-blocking area, above the first bank, and including a side surface that protrudes more than a side surface of the first bank toward the emission area and the light-transmitting area.

The auxiliary electrode may include a transparent conductive oxide.

The auxiliary electrode may contact the side surface of the first bank.

The emission area may include a first emission area and a second emission area spaced apart from each other, wherein the light-blocking area includes a first light-blocking area surrounding the first emission area, and a second light-blocking area surrounding the second emission area, and wherein the light-transmitting area surrounds the first light-blocking area and the second light-blocking area.

According to one or more embodiments of the present disclosure, a display device includes a first pixel electrode and a second pixel electrode above a substrate and spaced apart from each other, a pixel-defining layer above the substrate, and including respective portions above the first pixel electrode and the second pixel electrode, a first emissive layer and a first common electrode above the first pixel electrode, a second emissive layer and a second common electrode above the second pixel electrode, an auxiliary electrode between the first common electrode and the second common electrode, a first bank above the pixel-defining layer, between the first common electrode and the auxiliary electrode, and between the second common electrode and the auxiliary electrode, and a second bank above the first bank, and protruding beyond a side surface of the first bank.

The display device may further include a sub-auxiliary electrode above the second bank, and including a same material as the auxiliary electrode.

The display device may further include a first inorganic layer above the first common electrode, and a second inorganic layer above the second common electrode, and spaced apart from the first inorganic layer.

The details of one or more embodiments of the subject matter described in this specification are set forth in the accompanying drawings and the description below.

According to one or more embodiments of the present disclosure, optical devices are located in a subsidiary display area of a display panel that includes the light-transmitting areas, so that it is possible to decrease or prevent reduction of the light incident on the optical devices even though the optical devices overlap with the display panel.

It should be noted that aspects of the present disclosure are not limited to those described above and other aspects of the present disclosure will be apparent to those skilled in the art from the following descriptions.

### BRIEF DESCRIPTION OF THE DRAWINGS

The above and other aspects of the present disclosure will become more apparent by describing in detail embodiments thereof with reference to the attached drawings, in which:

FIG. 1 is a perspective view of a display device according to one or more embodiments of the present disclosure.

FIG. 2 is an exploded, perspective view showing a display device according to one or more embodiments of the present disclosure.

FIG. 3 is a plan view showing a display panel, a display circuit board, a display driver circuit, and a touch driver circuit according to one or more embodiments of the present disclosure.

FIG. 4 is a plan view showing a display panel, a display circuit board, a display driver circuit, and a touch driver circuit according to yet one or more other embodiments of the present disclosure.

FIG. 5 is a view showing a layout of a first display area of a display panel according to one or more embodiments of the present disclosure.

FIG. 6 is a view showing a layout of a second display area of a display panel according to one or more embodiments of the present disclosure.

FIG. 7 is a cross-sectional view showing in detail an example of the first display area of the display panel of FIG. 5.

FIG. 8 is an enlarged cross-sectional view showing in detail an example of the first emission area, the second emission area, and the first light-blocking area of FIG. 7.

FIG. 9 is a cross-sectional view showing in detail an example of the second display area of the display panel of FIG. 6.

FIG. 10 is an enlarged cross-sectional view showing in detail an example of the first emission area, the second emission area, the second light-blocking area, and the light-transmitting area of FIG. 9.

FIGS. 11 to 13 are enlarged cross-sectional views each showing in detail a second display area of a display panel according to one or more embodiments of the present disclosure.

FIGS. 14 and 15 are views each showing a layout of a second display area of a display panel according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

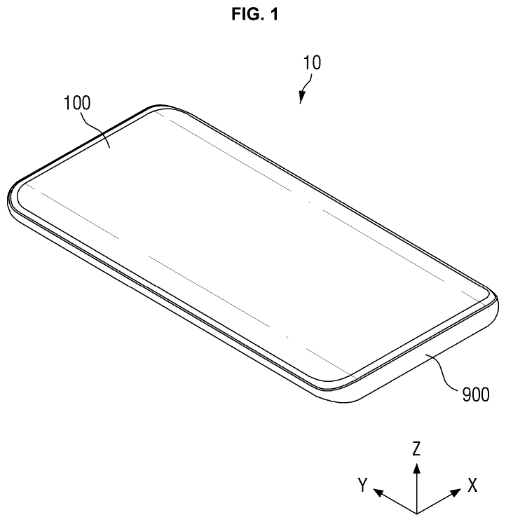

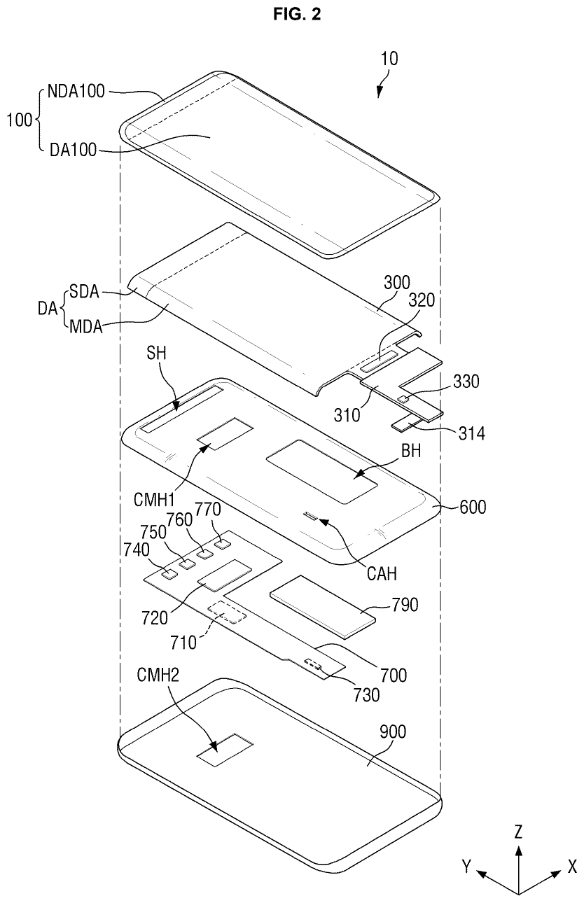

FIG. 1 is a perspective view of a display device according to one or more embodiments of the present disclosure. FIG. 2 is an exploded, perspective view showing a display device according to one or more embodiments of the present disclosure.

Referring to FIGS. 1 and 2, a display device 10 according to one or more embodiments of the present disclosure may be employed by portable electronic devices, such as a mobile phone, a smart phone, a tablet PC, a mobile communications terminal, an electronic notebook, an electronic book, a portable multimedia player (PMP), a navigation device and a ultra mobile PC (UMPC). Alternatively, the display device 10 may be used as a display unit of a television, a laptop computer, a monitor, an electronic billboard, or the Internet of Things (IOT). Alternatively, the display device 10 may be applied to wearable devices, such as a smart watch, a watch phone, a glasses-type display, and a head-mounted display (HMD) device. Alternatively, the display device 10 may be used as a center information display (CID) located at the instrument cluster, the center fascia, or the dashboard of a vehicle, as a room mirror display on the behalf of the side mirrors of a vehicle, as a display placed on the back of each of the front seats that is an entertainment system for passengers at the rear seats of a vehicle.

As used herein, the first direction (x-axis direction) may be the shorter side direction of the display device 10, for example, the horizontal direction of the display device 10. The second direction (y-axis direction) may be the longer side direction of the display device 10, for example, the vertical direction of the display device 10. A third direction (z-axis direction) may refer to the thickness direction of the display device 10.

The display device 10 may have a shape that is similar to a quadrangular shape when viewed from the top. For example, the display device 10 may have a shape similar to a quadrangular shape having shorter sides in a first direction (x-axis direction) and longer sides in a second direction (y-axis direction) when viewed from the top, as shown in FIG. 1. Each of the corners where the short side in the first direction (x-axis direction) meets the longer side in the second direction (y-axis direction) may be rounded with a curvature (e.g., predetermined curvature) or may be a right angle. The shape of the display device 10 when viewed from the top is not limited to a quadrangular shape, but may be formed in a shape similar to other polygonal shapes, a circular shape, or an elliptical shape.

The display device 10 may be formed to be flat. Alternatively, the display device 10 may be formed so that two sides facing each other are bent. For example, the display device 10 may be formed so that left and right sides are bent. Alternatively, the display device 10 may be formed so that all of the upper side, the lower side, the left side, and the right side are bent.

The display device 10 includes a cover window 100, a display panel 300, a display circuit board 310, a display driver circuit 320, a bracket 600, a main circuit board 700, optical devices 740, 750, 760, and 770, and a bottom cover 900.

The cover window 100 may be located on the display panel 300 to cover the front surface of the display panel 300 (as used herein, “located on” may mean “above”). Thus, the cover window 100 can protect the front surface of the display panel 300.

The cover window 100 may include a transmissive area DA100 corresponding to the display panel 300, and a non-transmissive area NDA100 corresponding to areas other than the display panel 300. The non-transmissive area NDA100 may be opaque. Alternatively, the non-transmissive area NDA100 may be formed as a decoration layer having a pattern that can be displayed to a user when no image is displayed.

The display panel 300 may be located under the cover window 100. The display panel 300 may include a display area DA including a main display area MDA and a subsidiary display area SDA. The main display area MDA may occupy most of the display area DA. The subsidiary display area SDA may be located on one side of the main display area MDA, for example, the upper side of the main display area MDA as shown in FIG. 2, but the present disclosure is not limited thereto.

The main display area MDA may not include a light-transmitting area that transmits light, and may include emission areas for displaying images. On the contrary, the subsidiary display area SDA may include a light-transmitting area that transmits light, as well as emission areas for displaying images. Therefore, the light transmittance of the subsidiary display area SDA may be higher than the light transmittance of the main display area MDA.

The subsidiary display area SDA may overlap with the optical devices 740, 750, 760, and 770 in the third direction (z-axis direction). Therefore, because light having passed through the subsidiary display area SDA can be incident on the optical devices 740, 750, 760, and 770, each of the optical devices 740, 750, 760, and 770 can detect light that is incident from the front side of the display device 10 even though the optical devices 740, 750, 760, and 770 overlap with the display panel 300.

The display panel 300 may be a light-emitting display panel including light-emitting elements. For example, the display panel 300 may be an organic light-emitting display panel using organic light-emitting diodes including organic emissive layer, a micro light-emitting diode display panel using micro LEDs, a quantum-dot light-emitting display panel including quantum-dot light-emitting diodes including an quantum-dot emissive layer, or an inorganic light-emitting display panel using inorganic light-emitting elements including an inorganic semiconductor. In the following description, an organic light-emitting display panel is employed as the display panel 300.

The display circuit board 310 and the display driver circuit 320 may be attached to one side of the display panel 300. The display circuit board 310 may be a flexible printed circuit board that can be bent, a rigid printed circuit board that is rigid and not bendable, or a hybrid printed circuit board including a rigid printed circuit board and a flexible printed circuit board.

The display driver circuit 320 may receive control signals and supply voltages through the display circuit board 310, and may generate and output signals and voltages for driving the display panel 300. The display driver circuit 320 may be implemented as an integrated circuit (IC), and may be attached to the display panel 300 by a chip-on-glass (COG) technique, a chip-on-plastic (COP) technique, or an ultrasonic bonding. It is, however, to be understood that the present disclosure is not limited thereto. For example, the display driver circuit 320 may be attached on the display circuit board 310.

A touch driver circuit 330 may be located on the display circuit board 310. The touch driver circuit 330 may be implemented as an integrated circuit, and may be attached to the upper surface of the display circuit board 310. The touch driver circuit 330 may be electrically connected to touch electrodes of the touch sensor layer of the display panel 300 through the display circuit board 310. The touch driver circuit 330 may output touch-driving signals to the touch electrodes, and may sense a voltage charged in capacitance of the touch electrodes.

The touch driver circuit 330 may generate touch data based on a change in the electric signal sensed by each of the touch electrodes to transmit the touch data to the main processor 710, and the main processor 710 may analyze the touch data to calculate the coordinates of the position where the touch input is made. Touches may include a physical contact and a near proximity. A physical contact refers to an object, such as the user's finger or a pen, being brought into contact with the cover window located on the sensor electrode layer. A near proximity refers to an object, such as a person's finger or a pen, being close to, yet spaced from, the cover window 100, such as hovering over it.

On the display circuit board 310, a power supply unit for supplying display-driving voltages for driving the display driver circuit 320 may be further located.

The bracket 600 may be located under the display panel 300. The bracket 600 may include plastic, metal, or both plastic and metal. In the bracket 600 there may be formed, a first camera hole CMH1 in which a first camera sensor 720 is inserted, a battery hole BH in which a battery is located, a cable hole CAH through which a cable 314 connected to the display circuit board 310 passes, and a light transmission hole SH in which the optical devices 740, 750, 760, and 770 are located. Alternatively, the bracket 600 may not include the light transmission hole SH, and may not overlap with the subsidiary display area SDA of the display panel 300.

The main circuit board 700 and a battery 790 may be located under the bracket 600. The main circuit board 700 may be either a printed circuit board or a flexible printed circuit board.

The main circuit board 700 may include a main processor 710, a first camera sensor 720, a main connector 730, and optical devices 740, 750, 760, and 770. The optical devices 740, 750, 760, and 770 may include a proximity sensor 740, an illuminance sensor 750, an iris sensor 760 and a second camera sensor 770.

The first camera sensor 720 may be located on both the upper and lower surfaces of the main circuit board 700, the main processor 710 may be located on the upper surface of the main circuit board 700, and the main connector 730 may be located on the lower surface of the main circuit board 700. The proximity sensor 740, the illuminance sensor 750, the iris sensor 760, and the second camera sensor 770 may be located on the upper surface of the main circuit board 700.

The main processor 710 may control all the functions of the display device 10. For example, the main processor 710 may output digital video data to the display driver circuit 320 through the display circuit board 310 so that the display panel 300 displays images. In addition, the main processor 710 may receive touch data from the touch driver circuit 330 to determine the coordinates of the user's touch, and then may execute an application indicated by the icon displayed at the coordinates of the user's touch. In addition, the main processor 710 may convert the first image data input from the first camera sensor 720 into digital video data, and may output the digital video data to the display driver circuit 320 through the display circuit board 310, so that the image captured by the first camera sensor 720 may be displayed on the display panel 300. In addition, the main processor 710 may control the display device 10 in response to sensor signals input from the proximity sensor 740, the illuminance sensor 750, the iris sensor 760, and the second camera sensor 770.

The main processor 710 may determine whether an object is located near the front surface of the display device 10 based on a proximity sensor signal input from the proximity sensor 740. In a call mode, in which a user is talking to another person using the display device 10, even if an object is proximate to the front surface of the display device 10, such that a user's touch is made, the main processor 710 may not 1 execute the application indicated by the icon displayed at the coordinates of the user's touch.

The main processor 710 may determine the brightness of the front side of the display device 10 according to an illuminance sensor signal input from the illuminance sensor 750. The main processor 710 may adjust the luminance of images displayed by the display panel 300 depending on the brightness of the front side of the display device 10.

The main processor 710 may determine whether a user's iris image is identical to an iris image previously stored in a memory based on an iris sensor signal input from the iris sensor 760. If it is determined that the user's iris image is identical to the iris image previously stored in the memory, the main processor 710 may unlock the display device 10 to display a home screen on the display panel 300.

The main processor 710 may generate digital video data according to second image data input from the second camera sensor 770. The main processor 710 outputs digital video data to the display driver circuit 320 through the display circuit board 310, so that the image captured by the second camera sensor 770 may be displayed on the display panel 300.

The first camera sensor 720 may process image frames, such as a still image and/or a video obtained by an image sensor, and may output the image frames to the main processor 710. The first camera sensor 720 may be a CMOS (complementary metal oxide semiconductor) image sensor or a CCD (charge coupled device) sensor. The first camera sensor 720 may be exposed to the lower surface of the bottom cover 900 through the second camera hole CMH2, and thus may capture an object or a background under the display device 10.

The cable 314, having passed through the cable hole CAH of the bracket 60, may be connected to main connector 730. Accordingly, the main circuit board 700 may be electrically connected to the display circuit board 310.

The proximity sensor 740 may be used for detecting whether an object is proximate to the front surface of the display device 10. The proximity sensor 740 may include a light source that outputs light, and a light receiver that receives light reflected by an object. The proximity sensor 740 may determine whether there is an object proximate to the front side of the display device 10 based on the amount of light reflected by the object. The proximity sensor 740 is located in line with the light transmission hole SH, the subsidiary display area SDA of the display panel 300, and the transmissive area DA100 of the cover window 100 in the thickness direction (z-axis direction). Therefore, a proximity sensor signal may be generated and output to the main processor 710 if there is an object proximate to the front surface of the display device 10.

The illuminance sensor 750 may detect the brightness of the front side of the display device 10. The illuminance sensor 750 may include a resistor whose resistance changes depending on the brightness of incident light. The illuminance sensor 750 may determine the brightness of the front side surface of the display device 10 based on the resistance of the resistor. The illuminance sensor 750 is located in line with the light transmission hole SH, the subsidiary display area SDA of the display panel 300, and the transmissive area DA100 of the cover window 100 in the thickness direction (z-axis direction). Therefore, an illuminance sensor signal may be generated depending on the brightness of the front surface of the display device 10, and may be output to the main processor 710.

The iris sensor 760 may be used for determining whether the captured image of the user's iris is identical to the iris image previously stored in the memory. The iris sensor 760 is located in line with the light transmission hole SH, the subsidiary display area SDA of the display panel 300, and the transmissive area DA100 of the cover window 100 in the thickness direction (z-axis direction). Therefore, the iris sensor 760 can capture a user's iris above the display device 10. The iris sensor 760 may generate the iris sensor signal depending on whether the image of the user's iris is identical to the iris image previously stored in the memory, and may output the iris sensor signal to the main processor 710.

The second camera sensor 770 may process image frames, such as still images and video obtained by an image sensor, and may output them to the main processor 710. The second camera sensor 770 may be a CMOS image sensor or a CCD sensor. The number of pixels of the second camera sensor 770 may be less than the number of pixels of the first camera sensor 720, and the size of the second camera sensor 770 may be smaller than that of the first camera sensor 720. The second camera sensor 770 is located in line with the light transmission hole SH, the subsidiary display area SDA of the display panel 300, and the transmissive area DA100 of the cover window 100 in the thickness direction (z-axis direction). Therefore, the second camera sensor 770 can capture objects or background above the display device 10.

The battery 790 may be located so that it does not overlap with the main circuit board 700 in the third direction (z-axis direction). The battery 790 may overlap with the battery hole BH of the bracket 600.

There may be further mounted on the main circuit board 700 a mobile communications module capable of transmitting/receiving a radio signal to/from at least one of a base station, an external terminal, or a server over a mobile communications network. The wireless signal may include various types of data depending on a voice signal, a video call signal, or a text/multimedia message transmission/reception.

The bottom cover 900 may be located under the main circuit board 700 and the battery 790. The bottom cover 900 may be fastened and fixed to the bracket 600. The bottom cover 900 may form the exterior of the lower surface of the display device 10. The bottom cover 900 may include plastic, metal, or plastic and metal.

A second camera hole CMH2 may be formed in the bottom cover 900, via which the lower surface of the first camera sensor 720 is exposed. The position of the first camera sensor 720 and the positions of the first and second camera holes CMH1 and CMH2 in line with the first camera sensor 720 are not limited to those according to the one or more embodiments corresponding to FIG. 2.

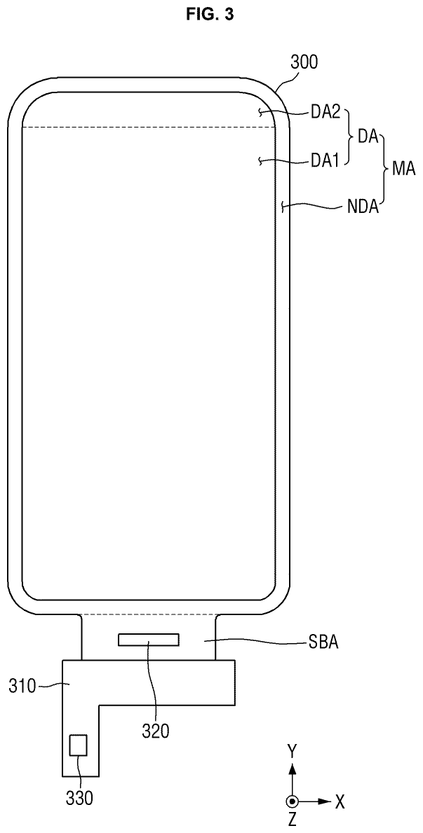

FIG. 3 is a plan view showing a display panel, a display circuit board, a display driver circuit, and a touch driver circuit according to one or more embodiments of the present disclosure.

Referring to FIG. 3, the display panel 300 may be a rigid display panel that is rigid, and thus is not easily bent, or may be a flexible display panel that is flexible, and thus can be easily bent, folded, or rolled. For example, the display panel 300 may be a foldable display panel that can be folded and unfolded, a curved display panel having a curved display surface, a bended display panel having a bent area other than the display surface, a rollable display panel that can be rolled and unrolled, and a stretchable display panel that can be stretched.

In addition, the display panel 300 may be implemented as a transparent display panel to allow a user to see an object or a background behind the display panel from the front side of the display panel 300 via light transmitting through the display panel 300. In addition, the display panel 300 may be implemented as a reflective display panel that can reflect an object or a background at the front side of the display panel 300.

The display panel 300 may include a main area MA, and a subsidiary area

SBA from one side of the main area MA. The main area MA may include a display area DA where images are displayed, and a non-display area NDA around the display area DA. The display area DA may occupy a majority of the main area MA. The display area DA may be generally located at the center of the main area MR. The non-display area NDA may be located on the outer side of the display area DA. The non-display area NDA may be defined as an edge of the display panel 300.

The display area DA may include a first display area DA1 and a second display area DA2. The first display area DA1 may be the main display area MDA, and the second display area DA2 may be the substrate display area SDA. The first display area DA1 may occupy a majority of the display area DA.

The first display area DA1 may not include a light-transmitting area that transmits light, and may include emission areas for displaying images. On the contrary, the second display area DA2 may include a light-transmitting area that transmits light, as well as emission areas for displaying images. Therefore, the light transmittance of the second display area DA2 may be higher than the light transmittance of the first display area DA1.

The second display area DA2 may overlap with the optical devices 740, 750, 760, and 770 in the third direction (z-axis direction). Therefore, because light having passed through the second display area DA2 can be incident on the optical devices 740, 750, 760, and 770, each of the optical devices 740, 750, 760, and 770 can detect light incident from the front side of the display device 10 even though the optical devices 740, 750, 760, and 770 overlap with the display panel 300.

The second display area DA2 may be located on one side of the first display area DA1, for example, the upper side of the first display area DA1 as shown in FIG. 3, but the present disclosure is not limited thereto. For example, the second display area DA2 may be located on the left, right, or lower side of the first display area DA1. Alternatively, the second display area DA2 may be located adjacent to the center of the first display area DA1, and may be surrounded by the first display area DA1 (e.g., in plan view). Alternatively, the second display area DA2 may be located adjacent to a corner of the display panel 300.

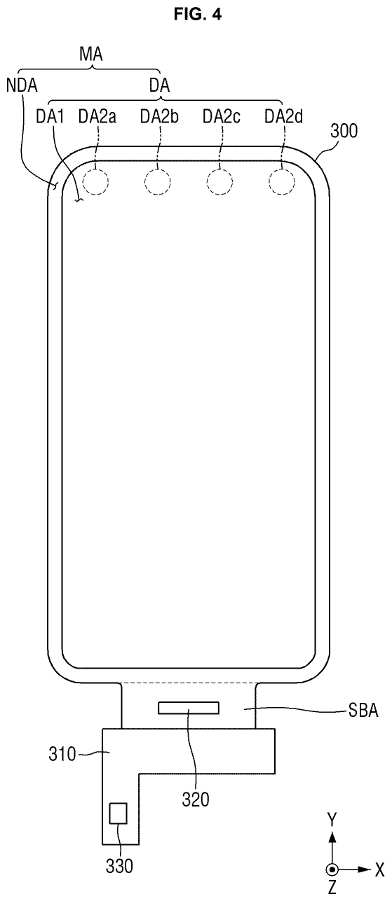

Alternatively, the display area DA may include a plurality of second display areas DA2a, DA2b, DA2c, and DA2d as shown in FIG. 4. The plurality of second display areas DA2a, DA2b, DA2c, and DA2d may be spaced apart from one another. Each of the plurality of second display areas DA2a, DA2b, DA2c, and DA2d may be surrounded by the first display area DA1 (e.g., in plan view).

One display area DA2a of the plurality of second display areas DA2a, DA2b, DA2c, and DA2d may be in line with the proximity sensor 740 in the third direction (z-axis direction). Therefore, even though the proximity sensor 740 overlaps with the display panel 300, the proximity sensor 740 can detect light incident from the front side of the display device 10 through the second display area DA2a.

One display area DA2b of the plurality of second display areas DA2a, DA2b, DA2c, and DA2d may be in line with the illuminance sensor 750 in the third direction (z-axis direction). Therefore, even though the illuminance sensor 750 overlaps with the display panel 300, the illuminance sensor 750 can detect light incident from the front side of the display device 10 through the second display area DA2b.

One display area DA2c of the plurality of second display areas DA2a, DA2b, DA2c, and DA2d may be in line with the iris sensor 760 in the third direction (z-axis direction). Therefore, even though the iris sensor 760 overlaps with the display panel 300, the iris sensor 760 can detect light incident from the front side of the display device 10 through the second display area DA2c.

One display area DA2d of the plurality of second display areas DA2a, DA2b, DA2c, and DA2d may be in line with the second camera sensor 770 in the third direction (z-axis direction). Therefore, even though the second camera sensor 770 overlaps with the display panel 300, the second camera sensor 770 can detect light incident from the front side of the display device 10 through the second display area DA2d.

Although the display area DA may include the four second display areas DA2a, DA2b, DA2c, and DA2d as shown in FIG. 4, the present disclosure is not limited thereto. The number of second display areas DA2a, DA2b, DA2c, and DA2d may depend on the number of the optical devices 740, 750, 760, and 770. The second display areas DA2a, DA2b, DA2c, and DA2d may be associated with the optical devices 740, 750, 760, and 770, respectively.

Although each of the plurality of second display areas DA2a, DA2b, DA2c, and DA2d may be formed in a circular shape, as shown in FIG. 4, the present disclosure is not limited thereto. For example, each of the plurality of second display areas DA2a, DA2b, DA2c, and DA2d may be formed in a polygonal or oval shape. In addition, although the second display areas DA2a, DA2b, DA2c, and DA2d may have the same size as shown in FIG. 4, the present disclosure is not limited thereto. The plurality of second display areas DA2a, DA2b, DA2c, and DA2d may have different respective sizes.

The subsidiary area SBA may protrude from one side of the main area MA in

the second direction (y-axis direction). As shown in FIG. 2, the length of the subsidiary area SBA in the first direction (x-axis direction) may be less than the length of the main area MA in the first direction (x-axis direction). The length of the subsidiary area SBA in the second direction (y-axis direction) may be less than the length of the main area MA in the second direction (y-axis direction). It is, however, to be understood that the present disclosure is not limited thereto. The sub-area SBA may be bent, and may be located under the display panel 300. In such case, the subsidiary area SBA may overlap with the main area MA in the thickness direction (z-axis direction).

The subsidiary area SBA of the display panel 300 may be bent to be located under the display panel 300. The subsidiary area SBA of the display panel 300 may overlap with the main area MA of the display panel 300 in the third direction (z-axis direction).

The display circuit board 310 and the display driver circuit 320 may be attached to the subsidiary area SBA of the display panel 300. The display circuit board 310 may be attached on pads of the subsidiary area SBA of the display panel 300 using a low-resistance, high-reliability material, such as an anisotropic conductive film and a self-assembly anisotropic conductive paste (SAP). The touch driver circuit 330 may be located on the display circuit board 310.

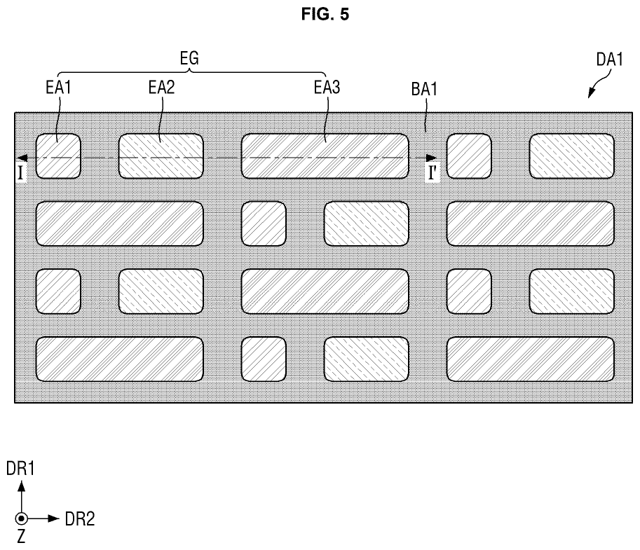

FIG. 5 is a view showing a layout of the first display area DA1 of the display panel 300 according to one or more embodiments of the present disclosure.

Referring to FIG. 5, the first display area DA1 may include emission areas EA1, EA2, and EA3 that emit light, and a first light-blocking area BA1 that blocks light.

The first light-blocking area BA1 may surround the emission areas EA1, EA2, and EA3 (e.g., in plan view). The first light-blocking area BA1 may be located in portions of the first display area DA1 excluding the emission areas EA1, EA2, and EA3. The emission areas EA1, EA2, and EA3 may include first emission areas EA1 for emitting light of a first color, second emission areas EA2 for emitting light of a second color, and third emission areas EA3 for emitting light of a third color. The first to third emission areas EA1, EA2, and EA3 may emit lights of different respective colors.

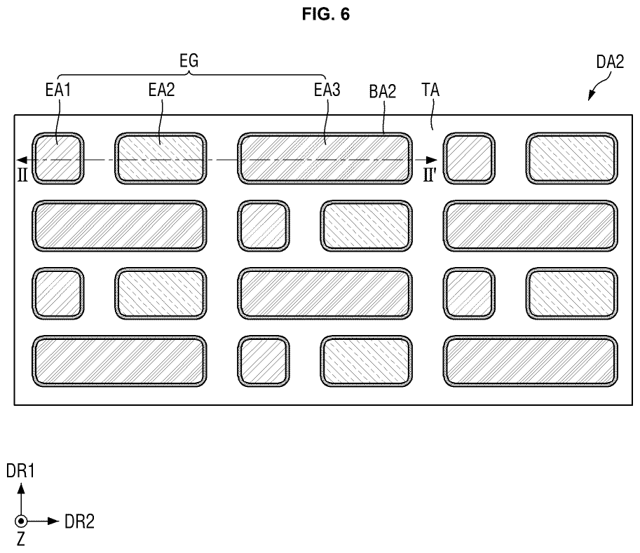

Each of the first to third emission areas EA1, EA2, and EA3 may have a rounded rectangular shape when viewed from the top, but the present disclosure is not limited thereto. Each of the first to third emission areas EA1, EA2, and EA3 may have a polygonal shape other than a rectangle, may have a circular shape, or may have an elliptical shape when viewed from the top. In addition, although the area of the third emission area EA3 is the largest while the first emission area EA1 is the smallest in the example shown in FIGS. 5 and 6, the present disclosure is not limited thereto.

One first emission area EA1, one second emission area EA2, and one third emission area EA3 may be defined as a single emission group EG for representing black-and-white or grayscale. That is to say, the black-and-white or grayscale may be represented by a combination of light emitted from one first emission area EA1, light emitted from one second emission area EA2, and light emitted from one third emission area EA3.

The emission areas EA1, EA2, and EA3 may be arranged sequentially and repeatedly. For example, the first emission area EA1, the second emission area EA2 and the third emission area EA3 may be arranged in the second direction DR2. The first emission area EA1 and the third emission area EA2 may be arranged alternately with the third emission area EA3 in the first direction DR1. The layout of the emission areas EA1, EA2, and EA3 is not limited to that shown in FIG. 5. The emission areas EA1, EA2, and EA3 may be arranged in a PenTile™ matrix, for example, a diamond PenTile™ matrix (PENTILE™ being a registered trademark of Samsung Display Co., Ltd., Republic of Korea). The first direction DR1 is an arbitrary direction in the plane of the display panel 300, and the second direction DR2 is a direction perpendicular to the first direction DR1.

FIG. 6 is a view showing a layout of the second display area DA2 of the display panel 300 according to one or more embodiments of the present disclosure.

Referring to FIG. 6, the second display area DA2 may include emission areas EA1, EA2, and EA3 that emit light, second light-blocking areas BA2 that block light, and a light-transmitting area TA that transmits light. There may be a plurality of second light-blocking areas BA2. Each of the light-blocking areas BA2 may be located between the light-transmitting area TA and the emission areas EA1, EA2, and EA3, and may surround one of the emission areas EA1, EA2, and EA3, respectively. The light-transmitting area TA transmits light incident on the display panel 300, and may surround the second light-blocking areas BA2 (e.g., in plan view). The light-transmitting area TA may be located in the second display area DA2 excluding the emission areas EA1, EA2, and EA3, and the second light-blocking areas BA2.

According to the one or more embodiments corresponding to FIG. 6, the optical devices 740, 750, 760, and 770 shown in FIG. 2 may be located in the subsidiary display area SDA of the display panel 300 including the light-transmitting areas TA. In this instance, the optical devices can detect light incident from the front side of the display device 10 thanks to the light-transmitting areas TA.

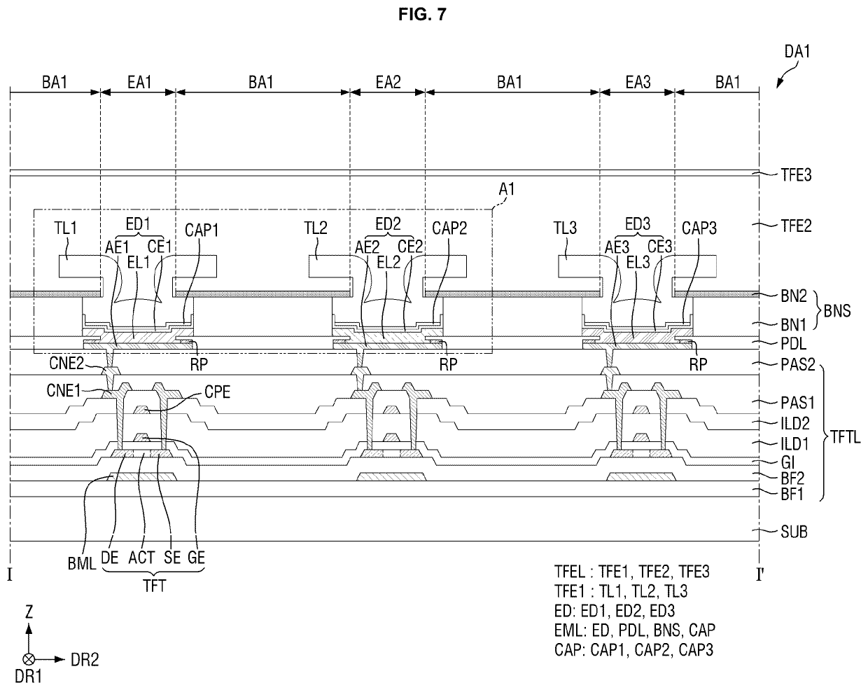

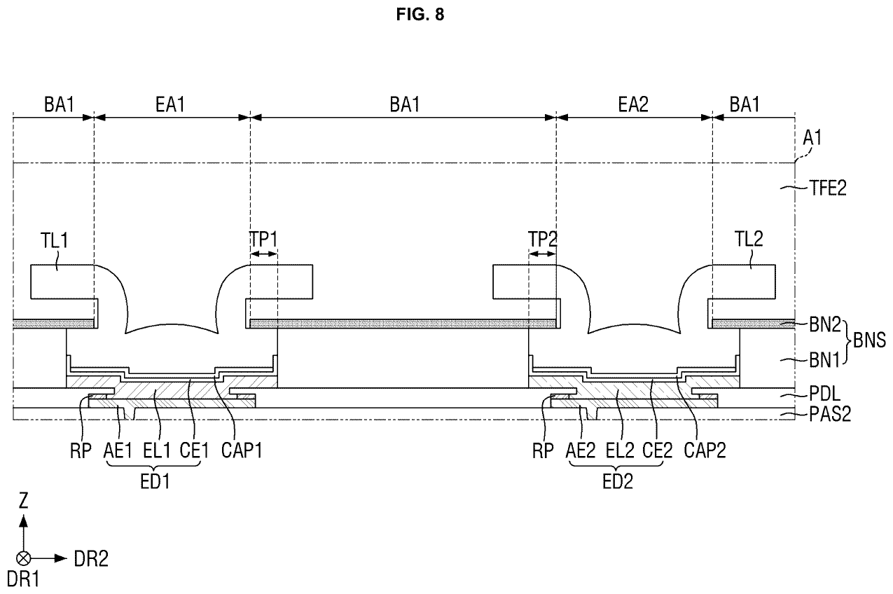

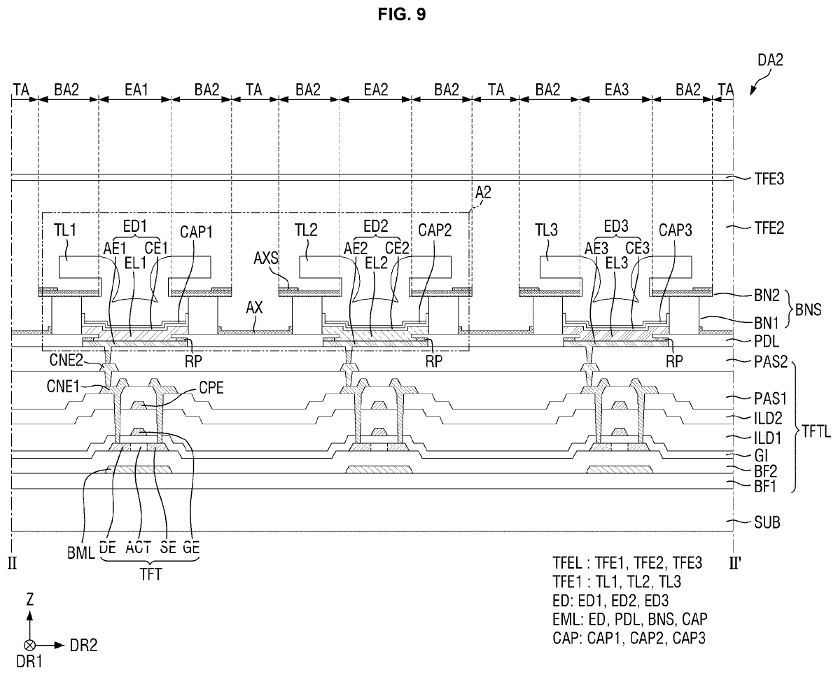

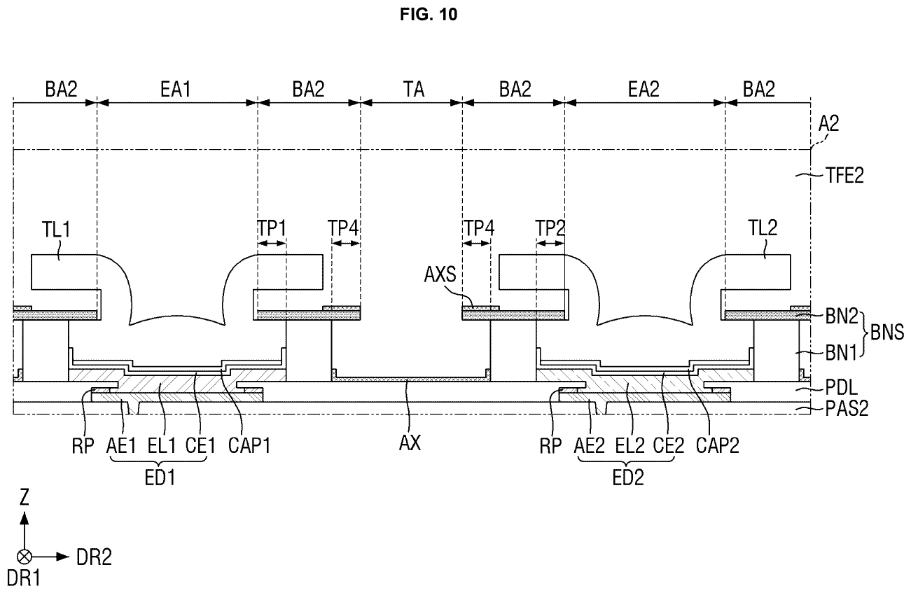

FIG. 7 is a cross-sectional view showing an example of the first display area DA1 of the display panel 300 taken along the line I-I′ of FIG. 5. FIG. 8 is an enlarged cross-sectional view showing in detail an example of the first emission area EA1, the second emission area EA2 and the first light-blocking area BA1 in the first display area DA1 of the display panel 300 according to one or more embodiments. For example, FIG. 8 is an enlarged view showing area A1 of FIG. 7. FIG. 9 is a cross-sectional view showing an example of the first display area DA1 of the display panel 300 taken along the line II-II′ of FIG. 6. FIG. 10 is an enlarged cross-sectional view showing in detail an example of a first emission area EA1, a second emission area EA2, second light-blocking areas BA2 and a light-transmitting area TA in the second display area DA2 of the display panel 300 according to one or more embodiments. For example, FIG. 10 is an enlarged view showing area A2 of FIG. 9.

Referring to FIGS. 7 and 9, the display panel 300 may include a substrate SUB, a thin-film transistor layer TFTL, an emission material layer EML, and a thin-film encapsulation layer TFEL.

The substrate SUB may be a base substrate or a base member. The substrate SUB may be a flexible substrate that can be bent, folded, or rolled. For example, the substrate SUB may include, but is not limited to, a polymer resin, such as polyimide PI. According to one or more other embodiments, the substrate SUB may include a glass material or a metal material.

The thin-film transistor layer TFTL may be located on the substrate SUB. The thin-film transistor layer TFTL may include a plurality of thin-film transistors forming pixel circuits of pixels. The thin-film transistor layer TFTL may further include scan lines, data lines, voltage lines, scan control lines, fan-out lines for connecting the display driver with the data lines, lead lines for connecting the display driver with the pads, etc. Each of the thin-film transistors may include a semiconductor region, a source electrode, a drain electrode, and a gate electrode. For example, when the scan driver is formed on one side of the non-display area NDA of the display panel 300, the scan driver may include thin-film transistors.

The thin-film transistor layer TFTL may be located in the display area DA, the non-display area NDA, and the subsidiary area SBA. The thin-film transistors in the pixels, the scan lines, the data lines, and the power supply lines on the thin-film film transistor layer TFTL may be located in the display area DA. The scan control lines and the fan-out lines in the thin-film transistor layer TFTL may be located in the non-display area NDA. The lead lines of the thin-film transistor layer TFTL may be located in the subsidiary area SBA.

The thin-film transistor layer TFTL may include a first buffer layer BF1, a bottom metal layer BML, a second buffer layer BF2, a thin-film transistor TFT, a gate insulator GI, a first interlayer dielectric layer ILD1, a capacitor electrode CPE, a second interlayer dielectric layer ILD2, a first connection electrode CNE1, a first passivation layer PAS1, a second connection electrode CNE2, and a second passivation layer PAS2.

The first buffer layer BF1 may be located on the substrate SUB. The first buffer layer BF1 may include an inorganic film capable of reducing or preventing permeation of air or moisture. For example, the first buffer layer BF1 may include a plurality of inorganic films stacked on one another alternately.

The bottom metal layer BML may be located on the first buffer layer BF1. For example, the bottom metal layer BML may be made up of a single layer or multiple layers of one of molybdenum (Mo), aluminum (AI), chromium (Cr), gold (Au), titanium (Ti), nickel (Ni), neodymium (Nd), or copper (Cu), or an alloy thereof.

The second buffer layer BF2 may cover the first buffer layer BF1 and the bottom metal layer BML. The second buffer layer BF2 may include an inorganic film capable of reducing or preventing permeation of air or moisture. For example, the second buffer layer BF2 may include a plurality of inorganic films stacked on one another alternately.

The thin-film transistor TFT may be located on the second buffer layer BF2, and may form a pixel circuit of each of a plurality of pixels. For example, the thin-film transistor TFT may be a driving transistor or a switching transistor of the pixel circuit. The thin-film transistor TFT may include a semiconductor layer ACT, a source electrode SE, a drain electrode DE, and a gate electrode GE.

The semiconductor layer ACT may be located on the second buffer layer BF2. The semiconductor layer ACT may overlap the bottom metal layer BML and the gate electrode GE in the thickness direction Z, and may be insulated from the gate electrode GE by the gate insulator GI. The material of a part of the semiconductor layer ACT may be made conductive to form the source electrode SE and the drain electrode DE.

The gate electrode GE may be located on the gate insulator GI. The gate electrode GE may overlap with the semiconductor layer ACT in the thickness direction Z with the gate insulator GI interposed therebetween.

The gate insulator GI may be located on the semiconductor layer ACT. For example, the gate insulator GI may cover the semiconductor layer ACT and the second buffer layer BF2, and may insulate the semiconductor layer ACT from the gate electrode GE. The gate insulator GI may include a contact hole through which the first connection electrode CNE1 passes.

The first interlayer dielectric layer ILD1 may cover the gate electrode GE and the gate insulator GI. The first interlayer dielectric layer ILD1 may include a contact hole through which the first connection electrode CNE1 passes. The contact holes of the first interlayer dielectric layer ILD1 may be connected to, or integral with, the contact holes of the gate insulator GI and the contact holes of the second interlayer dielectric layer ILD2.

The capacitor electrode CPE may be located on the first interlayer dielectric layer ILD1. The capacitor electrode CPE may overlap with the gate electrode GE in the thickness direction Z. The capacitor electrode CPE and the gate electrode GE may form a capacitance.

The second interlayer dielectric layer ILD2 may cover the capacitor electrode CPE and the first interlayer dielectric layer ILD1. The second interlayer dielectric layer ILD2 may include a contact hole through which the first connection electrode CNE1 passes. The contact hole of the second interlayer dielectric layer ILD2 may be connected to, or integral with, the contact hole of the first interlayer dielectric layer ILD1 and the contact hole of the gate insulator GI.

The first connection electrode CNE1 may be located on the second interlayer dielectric layer ILD2. The first connection electrode CNE1 may electrically connect the drain electrode DE of the thin-film transistor TFT with the second connection electrode CNE2. The first connection electrode CNE1 may be inserted into a contact hole formed in the second interlayer dielectric layer ILD2, the first interlayer dielectric layer ILD1, and the gate insulator GI to contact the drain electrode DE of the thin-film transistor TFT.

The first passivation layer PAS1 may cover the first connection electrode CNE1 and the second interlayer dielectric layer ILD2. The first passivation layer PAS1 can protect the thin-film transistor TFT. The first passivation layer PAS1 may include a contact hole through which the second connection electrode CNE2 passes.

The second connection electrode CNE2 may be located on the first passivation layer PAS1. The second connection electrode CNE2 may electrically connect the first connection electrode CNE1 with a respective pixel electrode AE1, AE2 or AE3 of a light-emitting element ED. The second connection electrode CNE2 may be inserted into a contact hole formed in the first passivation layer PAS1 to contact the first connection electrode CNE1.

The second passivation layer PAS2 may cover the second connection electrode CNE2 and the first passivation layer PAS1. The second passivation PAS2 may include contact holes through which the pixel electrodes AE1, AE2, and AE3 of the light-emitting elements ED pass.

The emission material layer EML may be located on the thin-film transistor layer TFTL. The emission material layer EML may include light-emitting elements ED, the pixel-defining layer PDL, a capping layer CAP (e.g., capping layers CAP1, CAP2, and CAP3), and a bank structure BNS. The light-emitting elements ED may include the pixel electrodes AE1, AE2, and AE3, emissive layers EL1, EL2, and EL3, and common electrodes CE1, CE2, and CE3, to emit light.

Referring to FIGS. 7 to 10, the display device 10 may include a plurality of emission areas EA1, EA2, and EA3 arranged in the display areas DA1 and DA2. The emission areas EA1, EA2, and EA3 may be defined as areas where the pixel electrodes AE1, AE2, and AE3, the emissive layers EL1, EL2, and EL3, and the common electrodes CE1, CE2, and CE3 respectively overlap one another in the thickness direction of the substrate SUB. The emission areas EA1, EA2, and EA3 may include a first emission area EA1, a second emission area EA2, and a third emission area EA3 that are spaced apart from one another, and that emit lights of the same color or of different respective colors.

The display device 10 may include a plurality of light-emitting elements ED1, ED2, and ED3 respectively located in different emission areas EA1, EA2, and EA3. The light-emitting elements ED1, ED2, and ED3 may include a first light-emitting element ED1 located in the first emission area EA1, a second light-emitting element ED2 located in the second emission area EA2, and a third light-emitting element ED3 located in the third emission area EA3.

The light-emitting elements ED1, ED2, and ED3 may include pixel electrodes AE1, AE2, and AE3, emissive layers EL1, EL2, and EL3, and common electrodes CE1,

CE2, and CE3, respectively. The light-emitting elements ED1, ED2, and ED3 located in different emission areas EA1, EA2, and EA3 may emit lights of different respective colors depending on the materials of the emissive layers EL1, EL2, and EL3. For example, the first light-emitting element ED1 located in the first emission area EA1 may emit green light with a peak wavelength ranging from about 510 nm to about 550 nm, the second light-emitting element ED2 located in the second emission area EA2 may emit red light with a peak wavelength ranging from about 610 nm to about 650 nm, and the third light-emitting element ED3 located in the third emission area EA3 may emit blue light with a peak wavelength ranging from about 440 nm to about 480 nm. The first to third emission areas EA1, EA2, and EA3 forming a single pixel may include the light-emitting elements ED1, ED2, and ED3 emitting lights of different respective colors to represent black-and-white or grayscale images. Alternatively, the emissive layers EL1, EL2, and EL3 may include two or more materials that emit lights of different respective colors, so that one emissive layer may emit mixed light. For example, the emissive layers EL1, EL2, and EL3 may contain a material for emitting red light as well as a material for emitting green light to emit yellow light, or may contain a material for emitting red light, a material for emitting green light, and/or a material for emitting blue light to emit white light.

The pixel electrodes AE1, AE2, and AE3 may be located on the second passivation layer PAS2. The pixel electrodes AE1, AE2, and AE3 may be located in the emission areas EA1, EA2, and EA3, respectively. The pixel electrodes AE1, AE2, and AE3 may respectively include a first pixel electrode PE1 located in the first emission area EA1, the second pixel electrode PE2 located in the second emission area EA2, and the third pixel electrode PE3 located in the third emission area EA3. The first pixel electrode AE1, the second pixel electrode AE2, and the third pixel electrode AE3 may be spaced apart from one another on the second passivation layer PAS2.

The pixel electrodes AE1, AE2, and AE3 may be electrically connected to the respective drain electrode DE of the thin-film transistor TFT through the respective first and second connection electrodes CNE1 and CNE2. Edges of the pixel electrodes AE1, AE, and AE3 spaced apart from one another may be covered by the pixel-defining layer PDL, and thus the first to third pixel electrodes AE1, AE2, and AE3 may be insulated from one another.

The pixel electrodes AE1, AE2, and AE3 may include a transparent conductive oxide or/and a conductive metal material, and may have a single-layer or multi-layer structure. The metal material may be one or more of silver (Ag), copper (Cu), aluminum (Al), nickel (Ni), lanthanum (La), titanium (Ti), or titanium nitride (TiN). The transparent conductive oxide may be one or more of ITO (Indium Tin Oxide), IZO (Indium Zinc Oxide), or ITZO (Indium Tin Zinc Oxide).

The emissive layers EL1, EL2, and EL3 may be located on the pixel electrodes AE1, AE2, and AE3, respectively. The emissive layers EL1, EL2, and EL3 may be organic emissive layers made of organic materials, and may be formed on the pixel electrodes AE1, AE2, and AE3 via a deposition process. The emissive layers EL1, EL2, and EL3 may have a multi-layer structure. A hole injection material, a hole transport material, a light-emitting material, an electron transport material, and/or an electron injection material each may form a layer. When the thin-film transistor TFT applies a voltage (e.g., predetermined voltage) to the pixel electrodes AE1, AE2, and AE3 of the light-emitting elements ED1, ED2, and ED3, and when the common electrode CE1, CE2, and CE3 of the light-emitting elements ED1, ED2, and ED3 receives a common voltage or cathode voltage, the holes and electrons may be injected and transported, and the holes and electrons may combine in the emissive layers EL1, EL2, and EL3 to emit light.

The emissive layers EL1, EL2, and EL3 may include a first emissive layer EL1, a second emissive layer EL2, and a third emissive layer EL3 located in different emission areas EA1, EA2, and EA3, respectively. The first emissive layer EL1 may be located on the first pixel electrode AE1 in the first emission area EA1, the second emissive layer EL2 may be located on the second pixel electrode AE2 in the second emission area EA2, and the third emissive layer EL3 may be located on the third pixel electrode AE3 in the third emission area EA3. The emissive layers EL1, EL2, and EL3 may emit lights of different respective colors, or one emissive layer EL1, EL2, and EL3 may emit mixed light. According to one or more embodiments of the present disclosure, the first emissive layer EL1 may emit green light, the second emissive layer EL2 may emit red light, and the third emissive layer EL3 may emit blue light.

The emissive layers EL1, EL2, and EL3 may be located on the upper surface of the pixel-defining layer PDL. The side surface of a residual pattern RP may be recessed from a side surface of the pixel-defining layer PDL. A portion of the emissive layers EL1, EL2, and EL3 may be located in the space between the pixel electrodes AE1, AE2, and AE3 and the pixel-defining layer PDL. The emissive layers EL1, EL2, and EL3 may contact the pixel-defining layer PDL, the residual pattern RP, and the pixel electrodes AE1, AE2, and AE3.

The common electrodes CE1, CE2, and CE3 may be located on the emissive layers EL1, EL2, and EL3. The common electrodes CE1, CE2, and CE3 include a transparent conductive material to allow lights generated in the emissive layers EL1, EL2, and EL3 to exit. The common electrodes CE1, CE2, and CE3 may receive a common voltage or a low-level voltage. When the pixel electrodes AE1, AE2, and AE3 receive the voltage equal to the data voltage, and when the common electrodes CE1, CE2, and CE3 receive the low-level voltage, a potential difference may be formed between the pixel electrodes AE1, AE2, and AE3 and the common electrodes CE1, CE2, and CE3, so that the emissive layers EL1, EL2, and EL3 may emit lights.

The common electrodes CE1, CE2, and CE3 may include a first common electrode CE1, a second common electrode CE2 and a third common electrode CE3 located in different emission areas EA1, EA2, and EA3, respectively. The first common electrode CE1 may be located on the first emissive layer EL1 in the first emission area EA1, the second common electrode CE2 may be located on the second emissive layer EL2 in the second emission area EA2, and the third common electrode CE3 may be located on the third emissive layer EL3 in the third emission area EA3. The first to third common electrodes CE1, CE2, and CE3 may be spaced apart from one another.

Capping layers CAP1, CAP2, and CAP3 may be located on the common electrodes CE1, CE2, and CE3. The capping layers CAP1, CAP2, and CAP3 may include an organic or inorganic insulating material, and may cover the patterns located on the light-emitting elements ED1, ED2, and ED3. The capping layers CAP1, CAP2, and CAP3 can reduce or prevent damage to the light-emitting elements ED1, ED2, and ED3 due to outside air. According to one or more embodiments, the capping layers CAP1, CAP2, and CAP3 may include an organic material, such as a-NPD, NPB, TPD, m-MTDATA, Alq₃, LiF and/or CuPc, or an inorganic material, such as aluminum oxide, titanium oxide, tantalum oxide, hafnium oxide, zinc oxide, silicon oxide, silicon nitride, and/or silicon oxynitride.

The capping layers CAP1, CAP2, and CAP3 may include a first capping layer CAP1, a second capping layer CAP2, and a third capping layer CAP3 located in different emission areas EA1, EA2, and EA3, respectively. The first to third capping layers CAP1, CAP2, and CAP3 may be spaced apart from one another.

The pixel-defining layer PDL may be located on the second passivation layer PAS2 to expose the upper surfaces of the pixel electrodes AE1, AE2, and AE3.

The pixel-defining layer PDL may include an inorganic insulating material. The pixel-defining layer PDL may include, but is not limited to, at least one of silicon nitride, silicon oxynitride, silicon oxide, titanium oxide, aluminum oxide, tantalum oxide, hafnium oxide, zinc oxide, or amorphous silicon.

The pixel-defining layer PDL may be located on the edges of the pixel electrodes AE1, AE2, and AE3, and may be spaced apart from upper surfaces of the pixel electrodes AE1, AE2, and AE3. The pixel-defining layer PDL may partially overlap with the upper surfaces of the pixel electrodes AE1, AE2, and AE3 in the thickness direction Z of the substrate SUB, but might not directly contact the upper surfaces of the pixel electrodes AE1, AE2, and AE3. The residual pattern RP may be located between the pixel-defining layer PDL and the pixel electrodes AE1, AE2, and AE3. It should be noted that the pixel-defining layer PDL may directly contact the side surfaces of the pixel electrodes AE1, AE2, and AE3. The side surfaces of the pixel-defining layer PDL may protrude toward the emission areas EA1, EA2, and EA3 further than the side surfaces of the second bank BN2.

The residual pattern RP may be located on the edges of each of the pixel electrodes AE1, AE2, and AE3. The pixel-defining layer PDL might not directly contact the upper surfaces of the pixel electrodes AE1, AE2, and AE3 due to the presence of the residual pattern RP. The residual pattern RP may be formed by removing a part of a sacrificial layer located on the pixel electrodes AE1, AE2, and AE3 in the process of fabricating the display device 10. The residual pattern RP may include a metal or oxide semiconductor material.

The display device 10 may include an auxiliary electrode AX located on the pixel-defining layer PDL. The auxiliary electrode AX may overlap with the light-transmitting area TA, but might not overlap with the emission areas EA1, EA2, and EA3. While the pixel electrodes AE1, AE2, and AE3 are connected to the transistors TFT of the transistor layer TFTL, the auxiliary electrode AX may not be connected to the transistors TFT of the transistor layer TFTL.

According to one or more embodiments of the present disclosure, the auxiliary electrode AX may include transparent conductive oxide (TCO) so that light incident from the outside can pass through it. The material of the transparent conductive oxide may include one or more of indium tin oxide (ITO), indium zinc oxide (IZO), indium tin zinc oxide (ITZO), zinc-indium-tin oxide (ZITO), indium-gallium-zinc oxide (IGZO), or zinc-tin oxide (ZTO).

The display device 10 may include a plurality of bank structures BNS located on the pixel-defining layer PDL. The bank structures BNS may have a structure in which banks BN1 and BN2 containing different materials are sequentially stacked on each other, and may include a plurality of openings including the emission areas EA1, EA2, and EA3, and the light-transmitting area TA. The bank structures BNS may define light-blocking areas BA1 and BA2. The bank structures BNS may overlap with the light-blocking areas BA1 and BA2, and might not overlap with the emission areas EA1, EA2, and EA3 and the light-transmitting area TA.

A first bank BN1 may be located on the pixel-defining layer PDL. A side surface of the first bank BN1 may be recessed more than a side surface of the pixel-defining layer PDL away from the emission areas EA1, EA2, and EA3. The side surface of the first bank BN1 may be recessed more than the side surface of the second bank BN2 away from the emission areas EA1, EA2, and EA3 or the light-transmitting area TA, which will be described later.

According to one or more embodiments, the first bank BN1 may include a metal material. According to one or more embodiments, the first bank BN1 may include aluminum (AI), an oxide of aluminum (AI), or an alloy of aluminum (Al).

The common electrodes CE1, CE2, and CE3 and the auxiliary electrode AX may be located on the side surface of the first bank BN1. The common electrodes CE1, CE2, and CE3 and the auxiliary electrode AX may directly contact the side surface of the first bank BN1. First and second ends of the common electrodes CE1, CE2, and CE3, and first and second ends of the auxiliary electrode AX may contact the side surface of the first bank BN1. In the first display area DA1, the common electrodes CE1, CE2, and CE3 of different light-emitting elements ED1, ED2, and ED3 may directly contact the first bank BN1, respectively. The first bank BN1 may include a conductive material, and accordingly the common electrodes CE1, CE2, and CE3 may be electrically connected with one another through the first bank BN1. In the second display area DA2, the first bank BN1 may be located between the common electrodes CE1, CE2, and CE3 and the auxiliary electrode AX. The auxiliary electrode AX may be located between the common electrodes CE1, CE2, and CE3, and the common electrodes CE1, CE2, and CE3 and the auxiliary electrode AX may contact the first bank BN1, and thus may be electrically connected to each other.

The emissive layers EL1, EL2, and EL3 may directly contact side surfaces of the first bank BN1. The contact area between the common electrodes CE1, CE2, and CE3 and the side surface of the first bank BN1 may be greater than the contact area between the emissive layers EL1, EL2 EL3 and the side surface of the first bank BN1. Portions of the common electrodes CE1, CE2, and CE3 contacting the side surface of the first bank BN1 may have a larger area, or may be located at a higher position on the side surface of the first bank BN1, than portions of the emissive layers EL1, EL2, and EL3 contacting the side surface of the first bank BN1. Because the common electrodes CE1, CE2, and CE3 of different light-emitting elements ED1, ED2, and ED3 are electrically connected through the first bank BN1, it may be suitable that they contact the first bank BN1 in a larger area.

The first bank BN1 may have an upper surface that is higher than the common electrodes CE1, CE2, and CE3, the capping layers CAP1, CAP2, and CAP3, and the auxiliary electrode AX. The height from the substrate SUB to the upper surface of the first bank BN1 may be greater than the height from the substrate SUB to the common electrodes CE1, CE2, and CE3, and may be greater than the height from the substrate SUB to the auxiliary electrode AX.

The second bank BN2 may be located on the first bank BN1. The second bank BN2 may define the light-blocking areas BA1 and BA2. In the first display area DA1, the second bank BN2 may define the boundaries between the emission areas EA1, EA2, and EA3 and the first light-blocking area BA1. In the second display area DA2, the second bank BN2 may define the boundaries between the emission areas EA1, EA2, and EA3 and the second light-blocking area BA2, and between the second light-blocking areas BA2 and the light-transmitting areas TA.

The second bank BN2 may include tips TP1, TP2, and TP4, which protrude from the first bank BN1. The second bank BN2 may partially overlap with the common electrodes CE1, CE2, and CE3, the capping layers CAP1, CAP2, and CAP3, and the auxiliary electrode AX in the thickness direction Z of the substrate SUB.

As the side surface of the second bank BN2 protrudes from the side surface of the first bank BN1, an undercut structure of the first bank BN1 may be formed below the tips TP1, TP2, and TP4 of the second bank BN2.

In the display device 10, the bank structure BNS includes protruding tips TP1 and TP2 toward the emission areas EA1, EA2, and EA3, and thus the emissive layers EL1, EL2, and EL3 and common electrodes CE1, CE2, and CE3 spaced apart from one another may be formed via deposition and etching processes, rather than a mask process. In addition, it is possible to form different layers individually in different emission areas EA1, EA2, and EA3 via a deposition process. For example, even though the emissive layers EL1, EL2, and EL3 and the common electrodes CE1, CE2, and CE3 of the light-emitting elements ED1, ED2, and ED3 are formed via a deposition process without using a mask, the deposited materials may not be connected between the emission areas EA1, EA2, and EA3, but may be disconnected by the tips TP1 and TP2 of the second bank BN2 with the bank structure BNS therebetween. By forming a material for forming a certain layer on the front surface of the display device 10, and by then etching and removing a layer formed at an unwanted location, it is possible to form different layers individually in different emission areas EA1, EA2, and EA3. In the display device 10, different light-emitting elements ED1, ED2, and ED3 may be respectively formed for different emission areas EA1, EA2, and EA3 via deposition and etching processes without using a mask process, and unnecessary configurations can be eliminated from the display device 10, and thus the non-display area can be reduced.

The second bank BN2 may include a metal material that is different from the metal material of the first bank BN1. It may be suitable that the metal material of the second bank BN2 is removed by dry etching along with the metal material of the first bank BN1, and is not etched by wet etching, or is more slowly etched than the first bank BN1. The first bank BN1 may include aluminum (Al), oxide of aluminum (Al), or an alloy of aluminum (Al), and the second bank BN2 may include titanium (Ti), oxide of titanium (Ti), or an alloy of titanium (Ti).

The tips TP1, TP2, and TP4 of the second bank BN2 may include a first tip TP1 adjacent to the first emission area EA1, a second tip TP2 adjacent to the second emission area EA2, and a fourth tip TP4 adjacent to the light-transmitting area TA. There may also be a third tip adjacent to the third emission area EA3. The side surface of the second bank BN2 may protrude toward the emission areas EA1, EA2, and EA3 or the light-transmitting area TA more than the side surface of the first bank BN1. The first tip TP1 of the second bank BN2 may surround the first emission area EA1, the second tip TP2 may surround the second emission area EA2, the third tip may surround the third emission area EA3, and the fourth tip TP4 may surround the light-transmitting area TA. The first tip TP1, the second tip TP2, the third tip, and the fourth tip TP4 of the second bank BN2 may have the same width.

The display device 10 may include a sub-auxiliary electrode AXS located on the second bank BN2. The sub-auxiliary electrode AXS may overlap with the second light-blocking area BA2 adjacent to the light-transmitting area TA. The sub-auxiliary electrode AXS may be located on the fourth tip TP4 of the second bank BN2.

The sub-auxiliary electrode AXS may be formed on the second bank BN2 when the auxiliary electrode AX is formed. According to one or more embodiments of the present disclosure, the sub-auxiliary electrode AXS may include the same material as the auxiliary electrode AX. The sub-auxiliary electrode AXS may include transparent conductive oxide (TCO). The transparent conductive oxide material may be one of the above-listed materials for the auxiliary electrode AX.

The thin-film encapsulation layer TFEL may be located on the upper and side surfaces of the emission material layer EML, and can protect the emission material layer EML. The thin-film encapsulation layer TFEL may include at least one inorganic film and at least one organic film for encapsulating the emission material layer EML.

The thin-film encapsulation layer TFEL may be located on the light-emitting elements ED1, ED2, and ED3, the auxiliary electrode AX, the sub-auxiliary electrode AXS, and the bank structure BNS, and may cover the light-emitting elements ED1, ED2, and ED3, the auxiliary electrode AX, the sub-auxiliary electrode AXS, and the bank structure BNS. The thin-film encapsulation layer TFEL may include at least one inorganic layer to reduce or prevent permeation of oxygen or moisture into the emission material layer EML. The thin-film encapsulation layer TFEL may include at least one organic layer to protect the emission material layer EML from foreign substances, such as dust.

The thin-film encapsulation layer TFEL may include a lower inorganic encapsulation film TFE1, an organic encapsulation film TFE2, and an upper inorganic encapsulation film TFE3 stacked on one another in this order.

Each of the lower encapsulation layer TFE1 and the upper encapsulation layer TFE3 may include one or more inorganic insulating materials. The inorganic insulating material may be one of silicon oxide, silicon nitride, or silicon oxynitride. For example, the inorganic insulating material may be aluminum oxide, titanium oxide, tantalum oxide, hafnium oxide, zinc oxide, silicon oxide, silicon nitride, and/or silicon oxynitride.

The organic encapsulation layer TFE2 may include a polymer-based material. The polymer-based material may include an acrylic resin, an epoxy resin, polyimide, polyethylene, etc. For example, the organic encapsulation layer TFEL2 may include an acrylic resin, such as polymethyl methacrylate and polyacrylic acid. The organic encapsulation layer TFE2 may be formed by curing a monomer or applying a polymer.

The lower inorganic encapsulation layer TFE1 may be located on the light-emitting elements ED1, ED2, and ED3 and the bank structure BNS. The lower inorganic encapsulation layer TFE1 may include a first inorganic layer TL1, a second inorganic layer TL2, and a third inorganic layer TL3 located in the different emission areas EA1, EA2, and EA3, respectively. The first inorganic layer TL1, the second inorganic layer TL2 and the third inorganic layer TL3 may include an inorganic insulating material to cover the light-emitting elements ED1, ED2, and ED3, respectively. The first inorganic layer TL1, the second inorganic layer TL2 and the third inorganic layer TL3 can reduce or prevent damage to the light-emitting elements ED1, ED2, and ED3 due to outside air.

Because the lower inorganic encapsulation layers TFE1 (e.g., TL1, TL2 and/or TL3) may be formed by chemical vapor deposition (CVD), they may be formed along the steps of the layer on which they are deposited. For example, the first inorganic layer TL1, the second inorganic layer TL2 and the third inorganic layer TL3 may form thin films even under the undercut by the tips of the bank structure BNS. The lower inorganic encapsulation layers TL1, TL2 and TL3 may be located along the upper, side and lower surfaces of the second bank BN2, the side surfaces of the first bank BN1, and the upper surfaces of the common electrodes CE1, CE2, and CE3. The lower inorganic encapsulation layers TL1, TL2 and TL3 may contact the lower surface of the second bank BN2 to reduce or prevent permeation of moisture from the outside air.

The first inorganic layer TL1 may not overlap with the second light-emitting element ED2 or the third light-emitting element ED3 but may be located only on the first light-emitting element ED1 and the surrounding bank structure BNS. The second inorganic layer TL2 may not overlap with the first light-emitting element ED1 or the third light-emitting element ED3 but may be located only on the second light-emitting element ED2 and the surrounding bank structure BNS. The third inorganic layer TL3 may not overlap with the first light-emitting element ED1 or the second light-emitting element ED2 but may be located only on the third light-emitting element ED3 and the surrounding bank structure BNS.

The first inorganic layer TL1 may be formed after the first common electrode CE1 is formed, the second inorganic layer TL2 may be formed after the second common electrode CE2 is formed, and the third inorganic layer TL3 may be formed after the third common electrode CE3 is formed. The first inorganic layer TL1, the second inorganic layer TL2 and the third inorganic layer TL3 may be spaced apart from each other on the bank structure BNS.

The lower inorganic encapsulation layers TL1, TL2 and TL3 may be located on the light-emitting elements ED1, ED2 and ED and the upper and lower surfaces of the surrounding second bank BN2 and may be spaced apart from the upper surface of the second bank BN2. That is to say, the lower inorganic encapsulation layers TL1, TL2 and TL3 may have an undercut structure on the second bank BN2. The space between the lower inorganic encapsulation layers TL1, TL2 and TL3 and the second bank BN2 may be created as the materials of the emissive layers EL1, EL2, and EL3 and the common electrodes CE1, CE2, and CE3 have been removed.

The organic encapsulation layer TFE2 is located on the auxiliary electrode AX, the sub-auxiliary electrode AXS, the second bank BN2, and the lower inorganic encapsulation layers TL1, TL2 and TL3. A portion of the organic encapsulation layer TFE2 may be located in the space between the lower inorganic encapsulation layers TL1, TL2 and TL3 and the upper surface of the second bank BN2. The second bank BN2, the organic encapsulation layer TFE2 and the lower inorganic encapsulation layer TL1, TL2 and TL3 may be sequentially located where the second bank BN2 and the lower inorganic encapsulation layers TL1, TL2 and TL3 overlap one another. In tip areas TP1 and TP2, the organic encapsulation layer TFE2 and the lower inorganic encapsulation layers TL1, TL2 and TL3 may be sequentially located on the second bank BN2, and the organic encapsulation layer TFE2 may be located over the lower inorganic encapsulation layers TL1, TL2 and TL3 again. In other words, some parts of the organic encapsulation layer TFE2 may be located on the upper surface of the second bank BN2 and between the lower inorganic encapsulation layers TL1, TL2 and TL3 on the tips TP1 and TP2 of the second bank BN2, and other portions thereof may be located over the lower inorganic encapsulation layers TL1, TL2 and TL3.

The entire upper surface of the second bank BN2 may contact the organic encapsulation layer TFE2 in the first display area DA1. A first lower surface of the lower inorganic encapsulation layers TL1, TL2 and TL3 may be a surface facing the upper surface of the second bank BN2. A first lower surface of the lower inorganic encapsulation layers TL1, TL2 and TL3 may contact the organic encapsulation layer TFE2. The organic encapsulation layer TFE2 may contact the side surfaces of the second bank BN2. The upper surface of the second bank BN2 may contact the sub-auxiliary electrode AXS and the organic encapsulation layer TFE2 in the second display area DA2.

The upper inorganic encapsulation layer TFE3 may be located on the organic encapsulation layer TFE2. The upper inorganic encapsulation layer TFE3 may include aluminum oxide, titanium oxide, tantalum oxide, hafnium oxide, zinc oxide, silicon oxide, silicon nitride, and/or silicon oxynitride.

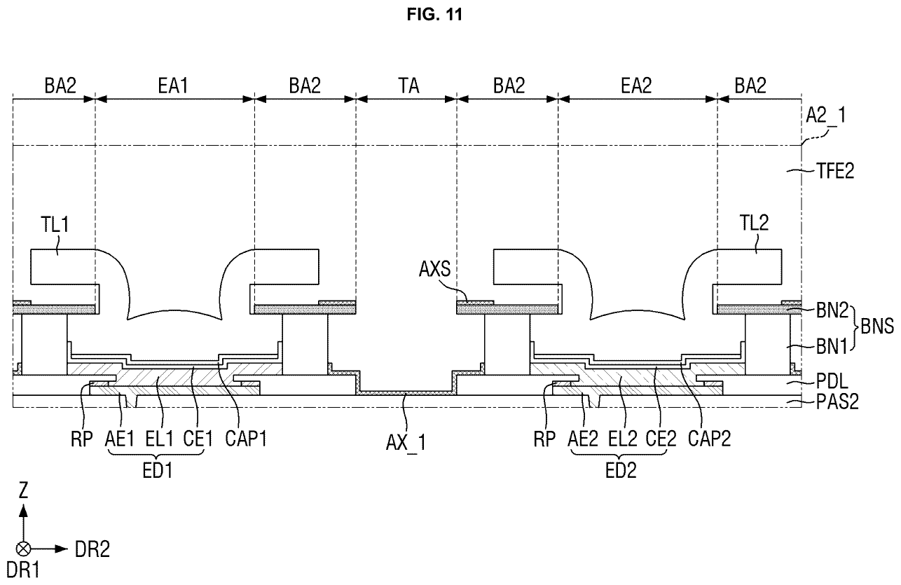

FIG. 11 is an enlarged, cross-sectional view of a second display area DA2 of a display panel 300 according to one or more embodiments. The one or more embodiments corresponding to FIG. 11 are different from the one or more embodiments corresponding to FIG. 10 in that at least a portion of a pixel-defining layer PDL in a light-transmitting area TA is removed, and a portion of an auxiliary electrode AX_1 may be located on a second passivation layer PAS2. The auxiliary electrode AX_1 may be located on side surfaces of the first bank BN1, a portion of the upper surface and side surfaces of the pixel-defining layer PDL, and the upper surface of the second passivation layer PAS2. Depending on the refractive index or light transmittance of the pixel-defining layer PDL, a portion of the pixel-defining layer PDL may be removed in the light-transmitting area TA. The other elements than the arrangement of the pixel-defining layer PDL and the auxiliary electrode AX_1 in the light-transmitting area TA are identical to those described above; and, therefore, the redundant descriptions will be omitted.

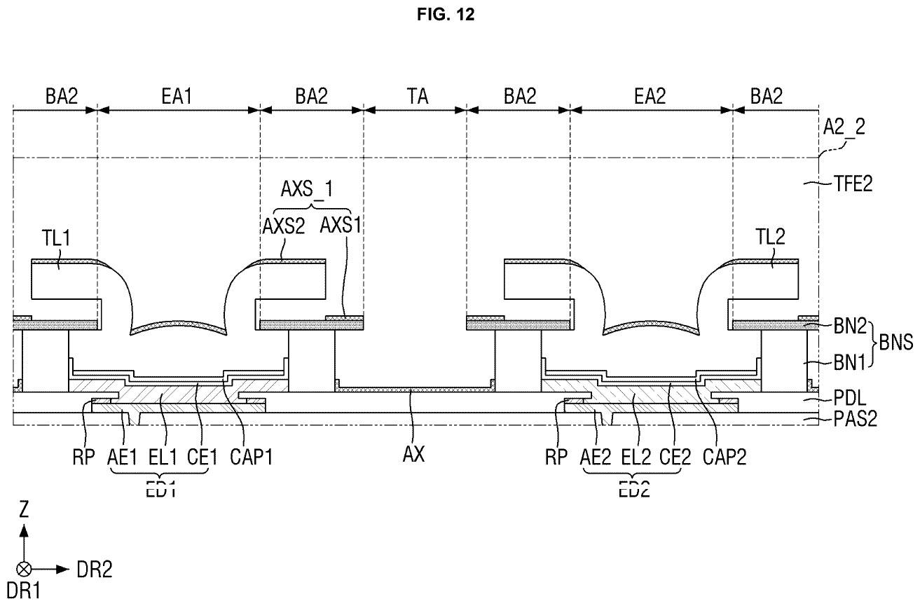

FIG. 12 is an enlarged, cross-sectional view of a second display area DA2 of a display panel 300 according to one or more embodiments. The one or more embodiments corresponding to FIG. 12 are different from the one or more embodiments corresponding to FIG. 10 in that a sub-auxiliary electrode AXS_1 may be located not only on a second bank BN2 but also on lower inorganic encapsulation layers TL1 and TL2. After first to third light-emitting elements ED1, ED2 and ED and the lower inorganic encapsulation layers TL1, TL2 and TL3 have been formed, the sub-auxiliary electrode AXS_1 and an auxiliary electrode AX are formed on the entire surface of the substrate SUB. The sub-auxiliary electrode AXS_1 may include a first sub-auxiliary electrode AXS1 located on the second bank BN2, and a second sub-auxiliary electrode AXS2 located on the lower inorganic encapsulation layers TL1, TL2 and TL3.

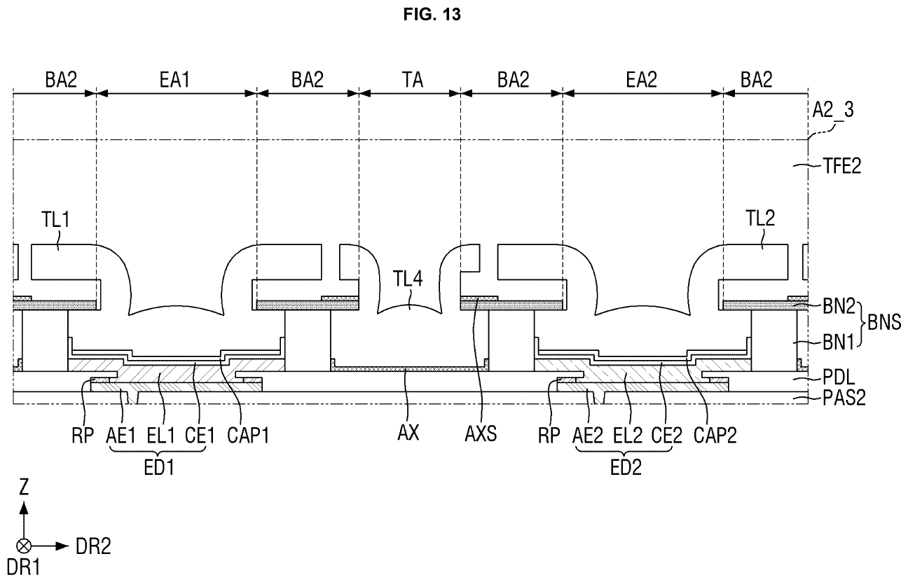

FIG. 13 is an enlarged, cross-sectional view of a second display area DA2 of a display panel 300 according to one or more embodiments. The one or more embodiments corresponding to FIG. 12 are different from the one or more embodiments corresponding to FIG. 10 in that a lower inorganic encapsulation layer TFE1 further includes a fourth inorganic layer TL4 located over an auxiliary electrode AX and a sub-auxiliary electrode AXS. The fourth inorganic layer TL4 may be formed together with one of the first to third inorganic layers TL1, TL2, and/or TL3, and may have the same material and film quality as one of the first to third inorganic layers TL1, TL2, and/or TL3. An organic encapsulation layer TFE2 may be located on the fourth inorganic layer TL4.

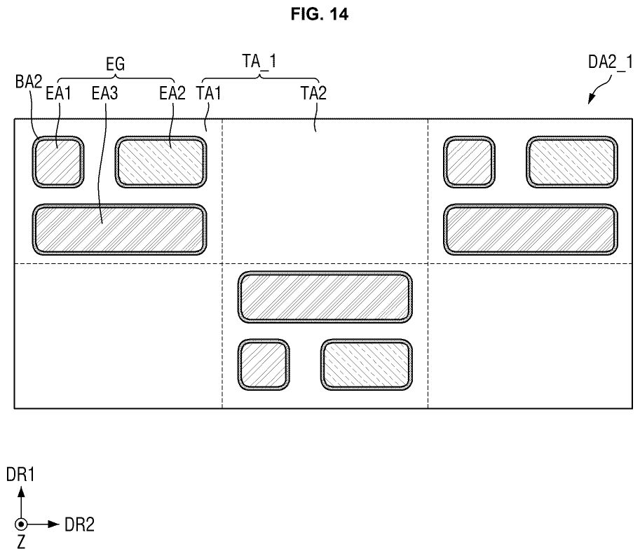

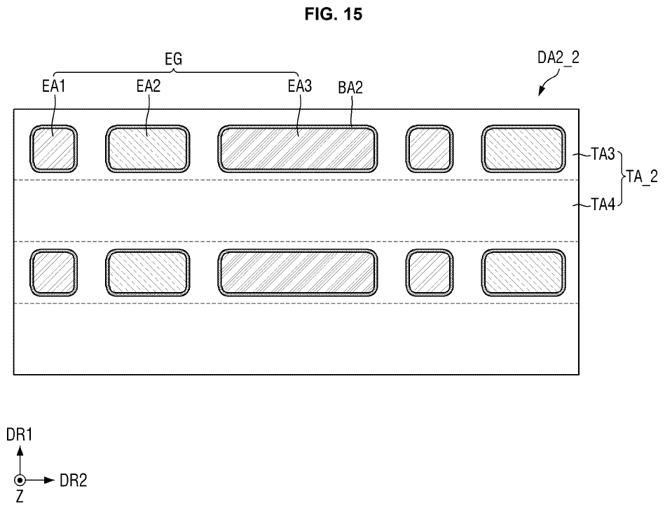

FIGS. 14 and 15 are views showing examples of layouts of the second display area DA2 of the display panel 300, respectively.

The second display areas DA2_1 and DA2_2 may have emission areas EA1, EA2, and EA3 with a lower density than the emission areas EA1, EA2, and EA3 of the first display area DA1. Due to the large light-transmitting areas TA_1 and TA_2, the number of emission areas EA1, EA2, and EA3 per unit area in the second display areas DA2_1 and DA2_2 may be less than the number of the emission areas EA1, EA2, and EA3 per unit area in the first display area DA1. In addition, due to the light-transmitting areas TA_1 and TA_2, the ratio of the area of the emission areas EA1, EA2, and EA3 of the second display areas DA2_1 and DA2_2 relative to the area of the second display areas DA2_1 and DA2_2 may be less than the ratio of the area of the emission areas EA1, EA2, and EA3 of the first display area DA1 relative to the area of the first display area DA1.

Referring to FIG. 14, a first emission area EA1 and a second emission area EA2 may be sequentially arranged in the second direction DR2. The first emission area EA1 and a third emission area EA3 may be sequentially arranged in the first direction DR1. The third emission area EA3 may extend in the second direction DR2, and may overlap with the first emission area EA1 and the second emission area EA2 in the first direction DR1. Adjacent first to third emission areas EA1, EA2, and EA3 may form an emission group EG. The second light-blocking area BA2 may surround the emission areas EA1, EA2, and EA3. The light-transmitting area TA_1 may include a first light-transmitting area TA1 surrounding the emission areas EA1, EA2, and EA3 and the second light-blocking area EA2, and a second light-transmitting area TA2 located between the emission groups EG. A plurality of emission groups EG may be spaced apart from one another in the first direction DR1 and the second direction DR2 with the second light-transmitting area TA4 therebetween. The sum of the areas of one emission group EG, and the second light-blocking area BA2 and the first light-transmitting area TA1 surrounding the one emission group EG, may be substantially equal to the area of the second light-transmitting area TA2.

Referring to FIG. 15, first to third emission areas EA1, EA2, and EA3 may be sequentially arranged in the second direction DR2, and may be surrounded by a second light-blocking area BA2 and a third light-transmitting area TA3. A plurality of emission groups EG may be spaced apart from one another in the first direction DR1 with a fourth light transmitting area TA4 therebetween. The fourth light-transmitting area TA4 may extend in the second direction DR2.

Although the embodiments of the present disclosure have been described with reference to the accompanying drawings, those skilled in the art would understand that various modifications and alterations may be made without departing from the aspects of the present disclosure. Therefore, it should be understood that the above-mentioned embodiments are not limiting, but illustrative in all aspects.

1 what is claimed is:

1. A display device comprising:
a pixel electrode above a substrate;
a pixel-defining layer above the substrate, and having a portion above the pixel electrode;
an emissive layer above the pixel electrode;
a common electrode above the emissive layer;
a first bank above the pixel-defining layer;
a second bank above the first bank, and protruding beyond a side surface of the first bank; and
an auxiliary electrode above the pixel-defining layer.

2. The display device of claim 1, wherein the second bank overlaps with the common electrode and the auxiliary electrode in a thickness direction of the substrate.

3. The display device of claim 1, wherein the first bank is between the auxiliary electrode and the common electrode.

4. The display device of claim 1, wherein the auxiliary electrode and the common electrode contact the side surface of the first bank.

5. The display device of claim 4, wherein the common electrode and the auxiliary electrode are electrically connected with each other.

6. The display device of claim 1, further comprising a sub-auxiliary electrode above the second bank, and comprising a same material as the auxiliary electrode.

7. The display device of claim 1, wherein the auxiliary electrode comprises transparent conductive oxide (TCO).

8. The display device of claim 1, wherein the first bank and the second bank comprise different respective metal materials.

9. The display device of claim 1, wherein a first distance, in plan view, between a first portion of a side surface of the second bank and a first portion of the side surface of the first bank adjacent to the common electrode is substantially equal to a second distance, in plan view, between a second portion of the side surface of the second bank and a second portion of the side surface of the first bank adjacent to the auxiliary electrode.

10. The display device of claim 1, further comprising a thin-film encapsulation layer above the common electrode and the auxiliary electrode.

11. The display device of claim 10, wherein the thin-film encapsulation layer comprises:
a lower inorganic encapsulation layer above the common electrode and the second bank;
an organic encapsulation layer above the lower inorganic encapsulation layer; and
an upper inorganic encapsulation layer above the organic encapsulation layer.

12. The display device of claim 11, wherein the lower inorganic encapsulation layer comprises a first inorganic layer above the common electrode, and a second inorganic layer above the auxiliary electrode, the first inorganic layer and the second inorganic layer being spaced apart from each other.

13. The display device of claim 11, further comprising a sub-auxiliary electrode above the second bank and the lower inorganic encapsulation layer, and comprising a same material as the auxiliary electrode.

14. A display device comprising:
a substrate comprising an emission area, a light-transmitting area, and a light-blocking area between the emission area and the light-transmitting area;
a light-emitting element above the substrate in the emission area;
an auxiliary electrode above the substrate in the light-transmitting area;
a first bank above the substrate in the light-blocking area; and
a second bank above the substrate in the light-blocking area, above the first bank, and comprising a side surface that protrudes more than a side surface of the first bank toward the emission area and the light-transmitting area.

15. The display device of claim 14, wherein the auxiliary electrode comprises a transparent conductive oxide.

16. The display device of claim 14, wherein the auxiliary electrode contacts the side surface of the first bank.

17. The display device of claim 14, wherein the emission area comprises a first emission area and a second emission area spaced apart from each other,
wherein the light-blocking area comprises a first light-blocking area surrounding the first emission area, and a second light-blocking area surrounding the second emission area, and
wherein the light-transmitting area surrounds the first light-blocking area and the second light-blocking area.

18. A display device comprising:
a first pixel electrode and a second pixel electrode above a substrate and spaced apart from each other;
a pixel-defining layer above the substrate, and comprising respective portions above the first pixel electrode and the second pixel electrode;
a first emissive layer and a first common electrode above the first pixel electrode;
a second emissive layer and a second common electrode above the second pixel electrode;
an auxiliary electrode between the first common electrode and the second common electrode;
a first bank above the pixel-defining layer, between the first common electrode and the auxiliary electrode, and between the second common electrode and the auxiliary electrode; and
a second bank above the first bank, and protruding beyond a side surface of the first bank.

19. The display device of claim 18, further comprising a sub-auxiliary electrode above the second bank, and comprising a same material as the auxiliary electrode.

20. The display device of claim 18, further comprising:
a first inorganic layer above the first common electrode; and
a second inorganic layer above the second common electrode, and spaced apart from the first inorganic layer.
